(19) United States
(12) Patent Application Publication
(10) Pub. No.: US 2025/0380541 A1
(43) Pub. Date: Dec. 11, 2025

(54) SEMICONDUCTOR DEVICE AND MANUFACTURING METHOD THEREOF

(71) Applicant: Japan Display Inc., Tokyo (JP)

(72) Inventors: Masumi NISHIMURA, Tokyo (JP); Ryo ONODERA, Tokyo (JP)

(73) Assignee: Japan Display Inc., Tokyo (JP)

(21) Appl. No.: 19/311,040

(22) Filed: Aug. 27, 2025

Related U.S. Application Data
(63) Continuation of application No. PCT/JP2024/002592, filed on Jan. 29, 2024.

(30) Foreign Application Priority Data
Mar. 9, 2023 (JP) 2023-036443

(51) Int. Cl. H10H 20/825; H10D 30/01; H10D 30/47; H10D 62/40; H10D 62/824; H10D 62/85; H10D 62/854; H10H 20/01; H10H 20/812; H10H 20/815; H10H 20/817

(52) U.S. Cl. CPC H10H 20/8252; H10D 30/015; H10D 30/027; H10D 30/475; H10D 62/402; H10D 62/824; H10D 62/8503; H10D 62/854; H10H 20/01335; H10H 20/815; H10H 20/817; H10H 20/812

(57) ABSTRACT

A semiconductor device includes a substrate, a buffer layer over the substrate, an n-type electrode overlapping the buffer layer, and an electron injection layer in contact with the n-type electrode over the buffer layer. The electron injection layer includes an n-type dopant and a first nitride semiconductor containing gallium. The first nitride semiconductor further contains at least one element of aluminum and indium.

### CROSS-REFERENCE TO RELATED APPLICATIONS

This application is a Continuation of International Patent Application No. PCT/JP2024/002592, filed on Jan. 29, 2024, which claims the benefit of priority to Japanese Patent Application No. 2023-036443, filed on Mar. 9, 2023, the entire contents of which are incorporated herein by reference.

### FIELD

An embodiment of the present invention relates to a semiconductor device using a compound semiconductor. Specifically, a semiconductor device is a light emitting diode (LED), a high electron mobility transistor (HEMT), or a field effect transistor (FET).

### BACKGROUND

Gallium nitride (GaN) is a direct bandgap semiconductor with a large bandgap. Focusing on the properties of gallium nitride, gallium nitride has the characteristics of high saturated electron mobility and a high breakdown voltage. An LED for a lighting device or a HEMT for a high-frequency power device has been developed by utilizing the characteristics of gallium nitride.

Gallium nitride is generally formed on a sapphire substrate at a high temperature of 800° C. to 1000° C. using MOCVD (Metal Organic Chemical Vapor Deposition) or HVPE (Hydride Vapor Phase Epitaxy). However, in recent years, an LED using GaN formed by sputtering have been developed (see, for example, Japanese laid-open patent publication No. 2012-119569).

### SUMMARY

A semiconductor device according to an embodiment of the present invention includes a substrate, a buffer layer over the substrate, an n-type electrode overlapping the buffer layer, and an electron injection layer in contact with the n-type electrode over the buffer layer. The electron injection layer includes an n-type dopant and a first nitride semiconductor containing gallium. The first nitride semiconductor further contains at least one element of aluminum and indium.

Further, a semiconductor device according to an embodiment of the present invention includes a substrate, a buffer layer over the substrate, a source electrode and a drain electrode overlapping the buffer layer, and an n-type semiconductor layer in contact with the source electrode the drain electrode over the buffer layer. The n-type semiconductor layer includes an n-type dopant and a first nitride semiconductor containing gallium. The first nitride semiconductor further contains at least one element of aluminum and indium.

Furthermore, a method for manufacturing a semiconductor device according to an embodiment of the present invention includes the steps of forming a buffer layer over a substrate and forming a semiconductor layer including a dopant and gallium over the buffer layer using a first sputtering target and a second sputtering target. The first sputtering target includes a nitride semiconductor containing the gallium. The second sputtering target includes the dopant and a metal containing at least one element of aluminum and indium.

### BRIEF DESCRIPTION OF DRAWINGS

FIG. 1 is a schematic cross-sectional view showing a configuration of a semiconductor device according to an embodiment of the present invention.

FIG. 2 is a schematic diagram illustrating a part of a method for manufacturing a semiconductor device according to an embodiment of the present invention.

FIG. 3 is a schematic cross-sectional view showing a configuration of a semiconductor device according to an embodiment of the present invention.

FIG. 4 is a schematic cross-sectional view showing a configuration of a semiconductor device according to an embodiment of the present invention.

FIG. 5 is a schematic cross-sectional view showing a configuration of a semiconductor device according to an embodiment of the present invention.

### DESCRIPTION OF EMBODIMENTS

There is a problem whereby it is difficult to control a concentration of a dopant in sputtering. In particular, it is very difficult to manufacture a doped GaN sputtering target.

In view of the above problem, an embodiment of the present invention can provide a semiconductor device including a nitride semiconductor in which a concentration of a dopant is controlled.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the specification, terms such as “first,” “second,” or “third” attached to each configuration are convenient terms used to distinguish each component, and have no further meaning unless otherwise explained.

In the specification and the drawings, the same reference numerals may be used when multiple components are identical or similar in general, and reference numerals with a lower or upper case letter of the alphabet may be used when the multiple components are distinguished. Further, reference numerals with a hyphen and a natural number may be used when multiple portions of one component are distinguished.

The following embodiments can be combined with each other as long as there is no technical contradiction.

### First Embodiment

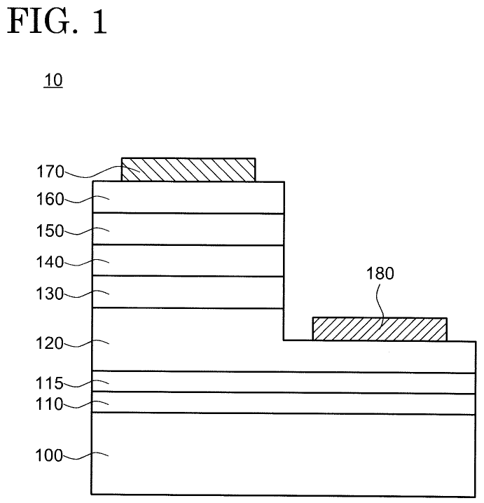

FIG. 1 is a schematic cross-sectional view showing a configuration of a semiconductor device 10 according to an embodiment of the present invention.

As shown in FIG. 1, the semiconductor device 10 includes a substrate 100, a buffer layer 110, an undoped nitride semiconductor layer 115, an electron injection layer 120, an electron transport layer 130, a light emitting layer 140, a hole transport layer 150, a hole injection layer 160, a p-type electrode 170, and an n-type electrode 180. The semiconductor device 10 is a so-called LED.

The buffer layer 110, the undoped nitride semiconductor layer 115, the electron injection layer 120, the electron transport layer 130, the light emitting layer 140, the hole transport layer 150, and the hole injection layer 160 are stacked in this order over the substrate 100. The p-type electrode 170 is provided on the hole injection layer 160 and is in contact with the hole injection layer 160. A portion of the electron injection layer 120 is exposed from the electron transport layer 130, and the n-type electrode 180 is provided on the exposed portion of the electron injection layer 120 and is in contact with the electron injection layer 120.

The substrate 100 is a support substrate for the semiconductor device 10. For example, a crystalline substrate such as a sapphire substrate, a silicon substrate, or a SiC substrate can be used as the substrate 100. Further, since the semiconductor device 10 is manufactured using sputtering and CVD, the substrate 100 only needs to have a heat resistance of about 600° C., for example. Therefore, an amorphous substrate can also be used as the substrate 100. For example, an amorphous glass substrate can be used as the amorphous substrate. Furthermore, a quartz substrate, or a resin substrate such as a polyimide substrate, an acrylic substrate, a siloxane substrate, or a fluororesin substrate can also be used as the amorphous substrate. The amorphous glass substrate or the resin substrate is a substrate that can be provided with a large area.

Although not shown in figures, a base layer may be provided between the substrate 100 and the buffer layer 110. The base layer can prevent diffusion of impurities from the substrate 100 or impurities from the outside (e.g., moisture or sodium (Na)). For example, a silicon nitride (SiNₓ) film or the like can be used as the base layer. Further, a laminated film of a silicon oxide (SiOₓ) film and a silicon nitride (SiNₓ) film can be used as the base layer.

The buffer layer 110 can control the crystal orientation of the undoped nitride semiconductor layer 115 formed by sputtering, and can improve the crystallinity of the undoped nitride semiconductor layer 115. Specifically, the buffer layer 110 can control the crystallinity of the undoped nitride semiconductor layer 115 so that the undoped nitride semiconductor layer 115 has a c-axis orientation (the c-axis is oriented in a direction substantially perpendicular to a surface of the buffer layer 110). A material having a hexagonal close-packed structure, a face-centered cubic structure, or a structure equivalent thereto can be used for the buffer layer 110. Here, the structure equivalent to the hexagonal close-packed structure or the face-centered cubic structure includes a crystal structure in which the c-axis is not 90 degrees with respect to the a-axis and the b-axis. The buffer layer 110 with the material having the hexagonal close-packed structure or the structure equivalent thereto can have an orientation in the (0001) direction, that is, in the c-axis direction with respect to the substrate 100 (hereinafter, referred to as the (0001) orientation of the hexagonal close-packed structure). Further, the buffer layer 110 with the material having the face-centered cubic structure or the structure equivalent thereto can have an orientation in the (111) direction with respect to the substrate 100 (hereinafter, referred to as the (111) orientation of the face-centered cubic structure). When the buffer layer 110 has the (0001) orientation of the hexagonal close-packed structure or the (111) orientation of the face-centered cubic structure, the crystal growth of the undoped nitride semiconductor layer 115 deposited on the buffer layer 110 in the c-axis direction is promoted. Therefore, the undoped nitride semiconductor layer 115 has the c-axis orientation with high crystallinity.

The crystallinity of the undoped nitride semiconductor layer 115 on the buffer layer 110 is affected by the surface state of the buffer layer 110. Therefore, it is preferable that the buffer layer 110 has a smooth surface with little unevenness. For example, the surface arithmetic mean roughness (Ra) of the buffer layer 110 is preferably less than 2.3 nm. Further, the root mean square roughness (Rq) of the surface of the buffer layer 110 is preferably less than 2.9 nm. When the surface roughness of the buffer layer 110 satisfies the above conditions, the undoped nitride semiconductor layer 115 has the c-axis orientation with further high crystallinity. In addition, the thickness of the buffer layer 110 is preferably greater than or equal to 50 nm.

A conductive material or an insulating material may be used for the buffer layer 110. The buffer layer 110 can be deposited by any method (apparatus) such as sputtering or CVD.

Titanium (Ti), magnesium (Mg), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), or thorium (Th), or an alloy thereof can be used as the conductive material of the buffer layer 110. Further, titanium nitride (TiNₓ), titanium oxide (TiOₓ), graphene, zinc oxide (ZnO), magnesium diboride (MgB₂), BiLaTiO, SrFeO, BiFeO, BaFeO, ZnFeO, or PMnN-PZT can be used as the conductive material of the buffer layer 110. In particular, it is preferable to use titanium, graphene, or ZnO for the buffer layer 110.

Further, silicon (Si), germanium (Ge), or an alloy thereof can be used as the conductive material of the buffer layer 110. Although silicon and germanium are semiconductor materials, they have higher conductivity than insulating materials described later. Therefore, in the present specification, it is described that semiconductor materials such as silicon and germanium used for the buffer layer 110 are included in the conductive material.

Aluminum nitride (AlN), aluminum oxide (Al₂O₃), silicon carbide (SiC), lithium niobate (LiNbO), BiLaTiO, SrFeO, SrFeO, BiFeO, BaFeO, ZnFeO, PMnN-PZT, or biological apatite (BAp) can be used as the insulating material of the buffer layer 110. In particular, it is preferable to use AlN or SiC for the buffer layer 110.

The crystal orientation of the undoped nitride semiconductor layer 115 is controlled by the buffer layer 110. Therefore, the undoped nitride semiconductor layer 115 can improve the crystallinity of the electron injection layer 120 deposited on the undoped semiconductor layer 115. For example, although a nitride semiconductor such as gallium nitride is used for the undoped nitride semiconductor layer 115, a material of the undoped nitride semiconductor layer 115 is not limited thereto.

The electron injection layer 120 can reduce the injection barrier of electrons supplied from the n-type electrode 180. Further, the electron transport layer 130 can transport the injected electrons to the light emitting layer 140. A nitride semiconductor containing an n-type dopant can be used for each of the electron injection layer 120 and the electron transport layer 130. For example, although the n-type dopant is silicon (Si) or germanium (Ge), the n-type dopant is not limited thereto.

The hole injection layer 160 can reduce the injection barrier of holes supplied from the p-type electrode 170. Further, the hole transport layer 150 can transport the injected holes to the light emitting layer 140. A nitride semiconductor containing a p-type dopant can be used for each of the hole injection layer 160 and the hole transport layer 150. For example, although the p-type dopant is magnesium (Mg) or zinc (Zn), the p-type dopant is not limited thereto.

A nitride semiconductor used for each of the electron injection layer 120, the electron transport layer 130, the hole transport layer 150, and the hole injection layer 160 is aluminum gallium nitride (AlGaN), indium gallium nitride (InGaN), or aluminum indium gallium nitride (AlInGaN). That is, the nitride semiconductor used for each of the electron injection layer 120, the electron transport layer 130, the hole transport layer 150, and the hole injection layer 160 is gallium nitride to which at least one of aluminum and indium has been added. Although the details are described later, each of the electron injection layer 120, the electron transport layer 130, the hole transport layer 150, and the hole injection layer 160 is deposited by co-sputtering using two sputtering targets. The nitride semiconductors of the electron injection layer 120, the electron transport layer 130, the hole transport layer 150, and the hole injection layer 160 may be the same or different from each other. When the electron injection layer 120 and the electron transport layer 130 are made of the same nitride semiconductor, the nitride semiconductors may have different concentrations of n-type dopants. Similarly, when the hole transport layer 150 and the hole injection layer 160 are made of the same nitride semiconductor, the nitride semiconductors may have different concentrations of p-type dopants.

The method of depositing each of the undoped nitride semiconductor layer 115, the electron injection layer 120, the electron transport layer 130, the hole transport layer 150, and the hole injection layer 160 is described later.

The light emitting layer 140 can emit light by recombination of the transported electrons and holes. Indium gallium nitride (InGaN) can be used for the light emitting layer 140. The light emitting layer 140 is deposited by sputtering using InGaN as a sputtering target. In addition, InGaN is an example of a sputtering target, and multiple sputtering targets may be used. For example, the sputtering targets of gallium nitride (GaN) and indium nitride (InN), the sputtering targets of gallium nitride (GaN) and indium (In), or the sputtering targets of gallium (Ga) and indium (In) can be used as multiple sputtering targets.

Here, a method for depositing the light emitting layer 140 is described. The light emitting layer 140 is deposited by sputtering using InGaN as a sputtering target.

The substrate 100 is placed in a vacuum chamber so as to face a sputtering target. Nitrogen may be supplied to the vacuum chamber separately from the sputtering gas (such as argon (Ar) or krypton (Kr)). For example, the nitrogen may be supplied using a nitrogen radical source. The sputtering power source may be a DC power source, an RF power source, or a pulsed DC power source.

The substrate 100 in the vacuum chamber may be heated. For example, the substrate 100 may be heated to a temperature between room temperature and 600° C., preferably between 100° C. and 400° C. This temperature is also applicable to amorphous glass substrates, which have low heat resistance. This temperature is also lower than the deposition temperature in MOCVD or HVPE.

After the vacuum chamber is sufficiently evacuated, the sputtering gas is supplied. Further, a voltage is applied between the substrate 100 and the sputtering target at a predetermined pressure to generate plasma, thereby depositing an InGaN film.

Although the method for depositing the InGaN film of the light emitting layer 140 is described above, the configuration or conditions of sputtering can be changed as appropriate. When gallium nitride (GaN), aluminum nitride (AlN), or aluminum indium nitride is used for the sputtering target, a GaN film, an AlN film, or an InAlGaN film can be deposited. The GaN film, the AlN film, or the InAlGaN film may be deposited using multiple sputtering targets.

The p-type electrode 170 and the n-type electrode 180 can function as an anode and a cathode, respectively. For example, although palladium (Pd) or gold (Au) can be used for the p-type electrode 170, the p-type electrode 170 is not limited thereto. For example, although indium (In) can be used for the n-type electrode 180, the n-type electrode 180 is not limited thereto. Each of the p-type electrode 170 and the n-type electrode 180 can be deposited by sputtering.

In the semiconductor device 10, the buffer layer 110 is deposited by sputtering or CVD, and each of the undoped nitride semiconductor layer 115, the electron injection layer 120, the electron transport layer 130, the light emitting layer 140, the hole transport layer 150, the hole injection layer 160, the p-type electrode 170, and the n-type electrode 180 is deposited by sputtering (including co-sputtering). As described above, the undoped nitride semiconductor layer 115 deposited on the buffer layer 110 has a highly crystalline c-axis orientation. Further, the electron transport layer 130, the light emitting layer 140, the hole transport layer 150, and the hole injection layer 160 deposited on a deposition surface having a highly crystalline c-axis orientation also have a highly crystalline c-axis orientation.

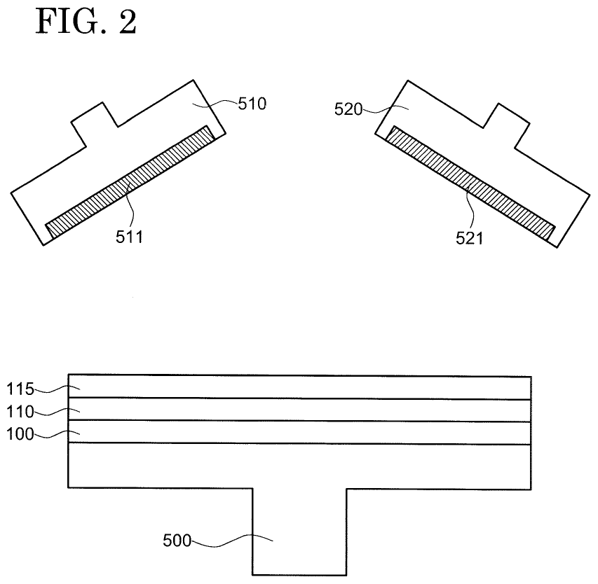

Here, the co-sputtering used in depositing the electron injection layer 120, the electron transport layer 130, the hole transport layer 150, and the hole injection layer 160 is described with reference to FIG. 2.

FIG. 2 is a schematic diagram illustrating a part of a method for manufacturing a semiconductor device 10 according to an embodiment of the present invention.

FIG. 2 shows a schematic diagram of a sputtering apparatus including a substrate support 500, a first sputtering target support 510, and a second sputtering target support 520. The substrate 100 over which the buffer layer 110 and the undoped nitride semiconductor layer 115 are formed is placed on the substrate support 500. The first sputtering target support 510 and the second sputtering target support 520 respectively have a first sputtering target 511 and a second sputtering target 521 arranged thereon. In the co-sputtering process, when a voltage is applied between the first sputtering target 511 and the second sputtering target 521 and the substrate 100 to generate a plasma, particles are ejected from each of the first sputtering target 511 and the second sputtering target 521 and deposited on the substrate 100 (more specifically, the undoped nitride semiconductor layer 115). As a result, a film containing elements constituting each of the first sputtering target 511 and the second sputtering target 521 is deposited on the substrate 100.

The first sputtering target 511 includes a nitride semiconductor such as gallium nitride (GaN). The second sputtering target 521 includes a metal such as aluminum (Al), indium (In), or aluminum indium (AlIN) to which a p-type or n-type dopant is added. When the second sputtering target 521 includes Al containing an n-type dopant, AlGaN containing an n-type dopant is deposited on the substrate 100. In this way, by using co-sputtering, an AlGaN film, an InGaN film, or an AlInGaN film containing a p-type or n-type dopant can be deposited.

It is also possible to use GaN and Si (an example of an n-type dopant) for the first sputtering target 511 and the second sputtering target 521, respectively. However, in this case, it is difficult to control the concentration of Si, and excessive Si is added to the GaN film deposited on the substrate 100. Further, it is also possible to use GaN and GaN doped with Si for the first sputtering target 511 and the second sputtering target 521, respectively. However, it is difficult to manufacture a sputtering target of GaN doped with Si. On the other hand, in the present embodiment, it is easy to adjust the amount of a p-type dopant or n-type dopant added to the metal in the second sputtering target 521, and the sputtering target is also easy to manufacture. Further, it is also possible to adjust the deposition rate of the first sputtering target 511 and the deposition rate of the second sputtering target 521 to control the concentration of a p-type dopant or n-type dopant in the nitride semiconductor film to be deposited. In particular, it is possible to deposited a nitride semiconductor film containing a lower concentration of a p-type dopant or n-type dopant in the present embodiment than in a conventional film.

As described above, in the present embodiment, a nitride semiconductor containing Al or In, which is a Group 13 element other than Ga, is used for the second sputtering target 521 in the co-sputtering process. Therefore, the main components of the electron injection layer 120, the electron transport layer 130, the hole transport layer 150, and the hole injection layer 160 deposited by co-sputtering are InGaN or AlInGaN, etc., rather than GaN.

In addition, although a detailed description is omitted, the undoped nitride semiconductor layer 115 can be deposited by using only the first sputtering target 511.

As described above, the semiconductor device 10 can be manufactured by sputtering. In particular, by adjusting the amount of a p-type dopant or n-type dopant in the second sputtering target 521 and the film formation rate, a nitride semiconductor film containing a p-type dopant or n-type dopant controlled to a predetermined concentration can be deposited. Therefore, the semiconductor device 10 can be manufactured inexpensively using a large-area substrate.

### Modification 1

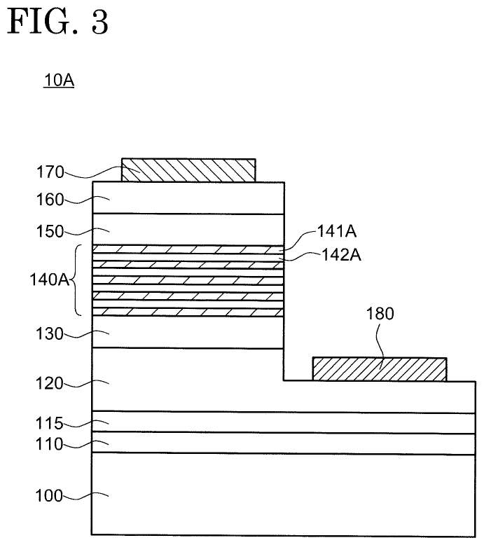

A modification of the semiconductor device 10 according to the embodiment of the present invention is described with reference to FIG. 3.

FIG. 3 is a schematic cross-sectional view showing a configuration of a semiconductor device 10A according to an embodiment of the present invention. In addition, a description of a configuration that is the same as or similar to that of the semiconductor device 10 may be omitted in the following description.

As shown in FIG. 3, the semiconductor device 10A includes the substrate 100, the buffer layer 110, the undoped nitride semiconductor layer 115, the electron injection layer 120, the electron transport layer 130, a light emitting layer 140A, the hole transport layer 150, the hole injection layer 160, the p-type electrode 170, and the n-type electrode 180. The semiconductor device 10A is a so-called LED.

The light emitting layer 140A has a laminated structure in which a first nitride semiconductor layer 141A and a second nitride semiconductor layer 142A are alternately and repeatedly laminated. The light emitting layer 140A has a so-called multi-quantum well (MQW) structure. The first nitride semiconductor layer 141A and the second nitride semiconductor layer 142A are indium gallium nitride (InGaN) and gallium nitride (GaN), respectively. The thickness of each of the first nitride semiconductor layer 141A and the second nitride semiconductor layer 142A is preferably less than or equal to 10 nm.

The first nitride semiconductor layer 141A is deposited by sputtering using InGaN for a sputtering target, and the second nitride semiconductor layer 142A is deposited by sputtering using GaN for a sputtering target.

As described above, the semiconductor device 10A can also be manufactured by sputtering, and therefore the semiconductor device 10A can be manufactured inexpensively using a large-area substrate.

### Second Embodiment

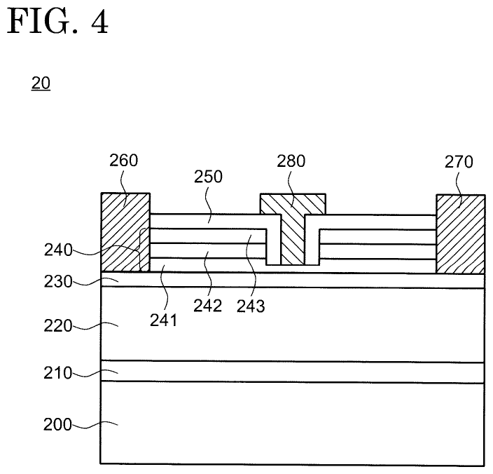

FIG. 4 is a schematic cross-sectional view showing a configuration of a semiconductor device 20 according to an embodiment of the present invention. In addition, a description of a configuration that is the same as or similar to that of the semiconductor device 10 may be omitted in the following description.

As shown in FIG. 4, the semiconductor device 20 includes a substrate 200, a buffer layer 210, a channel layer 220, an electron supply layer 230, a cap layer 240, a gate insulating layer 250, a source electrode 260, a drain electrode 270, and a gate electrode 280. The semiconductor device 20 is a so-called HEMT.

The buffer layer 210, the channel layer 220, the electron supply layer 230, and the cap layer 240 are stacked over the substrate 200 in this order. A portion of the electron supply layer 230 is exposed from the cap layer 240, and the source electrode 260 and the drain electrode 270 are provided on the exposed portion of the electron supply layer 230 and are in contact with the electron supply layer 230. The cap layer 240 includes a first nitride semiconductor layer 241, a second nitride semiconductor layer 242, and a third nitride semiconductor layer 243. The cap layer 240 is opened so that the first nitride semiconductor layer 241 is exposed, and the gate insulating layer 250 and the gate electrode 280 are provided in the opening. The gate insulating layer 250 is provided so as to cover the third nitride semiconductor layer 243. The gate electrode 280 is in contact with the first nitride semiconductor layer 241 in the opening.

The substrate 200 and the buffer layer 210 have the same configurations as the substrate 100 and the buffer layer 110 described in the First Embodiment, respectively.

The channel layer 220 is in contact with the electron supply layer 230. Materials of the channel layer 220 and the electron supply layer 230 are gallium nitride (GaN) and aluminum gallium nitride (n-AlGaN) containing an n-type dopant, respectively. That is, the channel layer 220 and the electron supply layer 230 are different nitride semiconductors. Therefore, a heterojunction having a band discontinuity is formed at the interface between the channel layer 220 and the electron supply layer 230, and a two-dimensional electron gas (2DEG) having a high concentration and high mobility is generated in the vicinity of the junction interface (specifically, in the vicinity of the interface in the channel layer 220) due to spontaneous polarization and the piezoelectric effect. In addition, the electron supply layer 230 may be referred to as an n-type semiconductor layer in the following description.

The channel layer 220 is deposited by sputtering using GaN for a sputtering target, and the electron supply layer 230 can be deposited by co-sputtering using GaN for the first sputtering target 511 and Al doped with an n-type dopant for the second sputtering target 521.

The cap layer 240 can increase the number of conduction electrons in the two-dimensional electron gas by the piezoelectric effect. Each of the first nitride semiconductor layer 241 and the third nitride semiconductor layer 243 is indium gallium nitride containing an n-type dopant (n-InGaN). The second nitride semiconductor layer 242 is aluminum nitride (AlN). Each of the first nitride semiconductor layer 241 and the third nitride semiconductor layer 243 can be deposited by co-sputtering. In the co-sputtering process, GaN is used for the first sputtering target 511, and In to which an n-type dopant is added is used for the second sputtering target 521. Thus, an n-InGaN film with a controlled concentration of the n-type dopant can be deposited. The second nitride semiconductor layer 242 is deposited by sputtering using AlN for a sputtering target.

Silicon oxide (SiOₓ), aluminum oxide (AlOₓ), hafnium oxide (HfOₓ), lanthanum oxide (LaOₓ), silicon nitride (SiNₓ), aluminum nitride (AlNₓ), or the like can be used for the gate insulating layer 250. The gate insulating layer 250 may be a single film or a laminated film. The gate insulating layer 250 is deposited by sputtering or CVD.

A metal such as aluminum (Al), titanium (Ti), platinum (Pt), nickel (Ni), tantalum (Ta), or gold (Au), or an alloy thereof can be used for each of the source electrode 260 and the drain electrode 270. Each of the source electrode 260 and the drain electrode 270 can be a single film or a laminated film. The source electrode 260 and the drain electrode 270 are deposited by sputtering.

A metal such as aluminum (Al), titanium (Ti), platinum (Pt), nickel (Ni), tantalum (Ta), or gold (Au), or an alloy thereof can be used for the gate electrode 280. The gate electrode 280 may be a single film or a laminated film. The gate electrode 280 is deposited by sputtering.

In addition, the semiconductor device 20 may have a configuration in which the gate insulating layer 250 is not provided. When the gate insulating layer 250 is not provided, the gate electrode 280 is in contact with the cap layer 240 and functions as a so-called Schottky gate electrode.

As described above, the semiconductor device 20 can be manufactured using sputtering. In particular, by adjusting the amount of an n-type dopant in the second sputtering target 521 and the deposition rate, a nitride semiconductor containing an n-type dopant controlled to a predetermined concentration can be deposited. Therefore, the semiconductor device 20 can be manufactured inexpensively using a large-area substrate.

### Third Embodiment

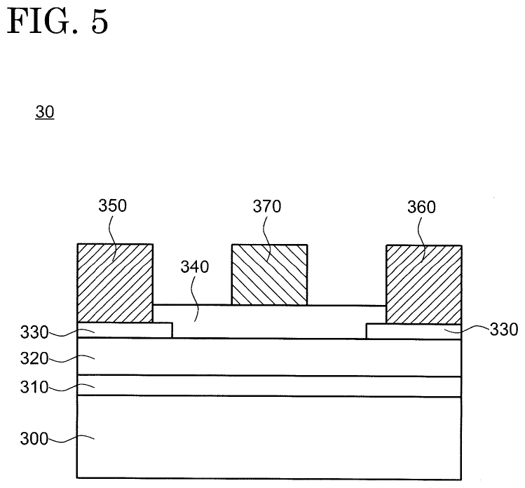

FIG. 5 is a schematic cross-sectional view showing a configuration of a semiconductor device 30 according to an embodiment of the present invention. In addition, a description of a configuration that is the same as or similar to that of the semiconductor device 10 or the semiconductor device 20 may be omitted in the following description.

As shown in FIG. 5, the semiconductor device 30 includes a substrate 300, a buffer layer 310, a channel layer 320, an n-type semiconductor layer 330, a gate insulating layer 340, a source electrode 350, a drain electrode 360, and a gate electrode 370. The semiconductor device 30 is a so-called FET.

The buffer layer 310 and the channel layer 320 are stacked in this order over the substrate 300. The n-type semiconductor layer 330 is provided between the channel layer 320 and the source electrode 350 or the drain electrode 360. The gate insulating layer 340 is provided so as to cover the channel layer 320. The gate insulating layer 340 is provided on the gate insulating layer 340, separated from the source electrode 350 and the drain electrode 360.

The substrate 300 and the buffer layer 310 have the same configuration as the substrate 100 and the buffer layer 110 described in the First Embodiment, respectively. The channel layer 320, the gate insulating layer 340, the source electrode 350, the drain electrode 360, and the gate electrode 370 have the same configuration as the channel layer 220, the gate insulating layer 250, the source electrode 260, the drain electrode 270, and the gate electrode 280 described in the Second Embodiment, respectively.

The n-type semiconductor layer 330 can reduce the contact resistance between the channel layer 320 and the source electrode 350 or the drain electrode. A material of the n-type semiconductor layer 330 is aluminum gallium nitride (n-AlGaN) containing an n-type dopant. The n-type semiconductor layer 330 can be deposited by co-sputtering. In the co-sputtering process, GaN is used for the first sputtering target 511, and Al to which an n-type dopant is added is used for the second sputtering target 521. Thus, an n-AlGaN film with a controlled concentration of the n-type dopant can be deposited.

In addition, indium gallium nitride containing an n-type dopant (n-InGaN) or aluminum indium gallium nitride containing an n-type dopant (n-AlInGaN) may be used for the n-type semiconductor layer 330.

As described above, the semiconductor device 30 can be manufactured using sputtering. In particular, by adjusting the amount of n-type dopant in the second sputtering target 521 and the deposition rate, a nitride semiconductor containing an n-type dopant controlled to a predetermined concentration can be deposited. Therefore, the semiconductor device 30 can be manufactured inexpensively using a large-area substrate.

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device, comprising:
a substrate;
a buffer layer over the substrate;
an n-type electrode overlapping the buffer layer; and
an electron injection layer in contact with the n-type electrode over the buffer layer,
wherein the electron injection layer comprises an n-type dopant and a first nitride semiconductor containing gallium, and
wherein the first nitride semiconductor further contains at least one element of aluminum and indium.

2. The semiconductor device according to claim 1, further comprising:
a p-type electrode overlapping the buffer layer; and
a hole injection layer in contact with the p-type electrode over the buffer layer,
wherein the hole injection layer comprises a p-type dopant and a second nitride semiconductor containing gallium, and
wherein the second nitride semiconductor further contains at least one element of aluminum and indium.

3. The semiconductor device according to claim 1, wherein the buffer layer comprises at least one of silicon, titanium, graphene, and zinc oxide.

4. The semiconductor device according to claim 1, wherein the substrate is an amorphous substrate.

5. The semiconductor device according to claim 4, wherein the amorphous substrate is an amorphous glass substrate.

6. A semiconductor device, comprising:
a substrate;
a buffer layer over the substrate;
a source electrode and a drain electrode overlapping the buffer layer; and
an n-type semiconductor layer in contact with the source electrode and the drain electrode over the buffer layer,
wherein the n-type semiconductor layer comprises an n-type dopant and a first nitride semiconductor containing gallium, and
wherein the first nitride semiconductor further contains at least one element of aluminum and indium.

7. The semiconductor device according to claim 6, further comprising a channel layer between the buffer layer and the n-type semiconductor layer,
wherein the channel layer comprises a second nitride semiconductor containing gallium.

8. The semiconductor device according to claim 6, wherein the buffer layer comprises at least one of silicon, titanium, graphene, and zinc oxide.

9. The semiconductor device according to claim 6, wherein the substrate is an amorphous substrate.

10. The semiconductor device according to claim 9, wherein the amorphous substrate is an amorphous glass substrate.

11. A method for manufacturing a semiconductor device, comprising the steps of:
forming a buffer layer over a substrate; and
forming a semiconductor layer comprising a dopant and gallium over the buffer layer using a first sputtering target and a second sputtering target,
wherein the first sputtering target comprises a nitride semiconductor containing the gallium, and
wherein the second sputtering target comprises the dopant and a metal containing at least one element of aluminum and indium.

12. The method for manufacturing a semiconductor device according to claim 11, wherein the dopant is one of Si, Ge, Mg, and Zn.

13. The method for manufacturing a semiconductor device according to claim 11, wherein the buffer layer comprises at least one of silicon, titanium, graphene, and zinc oxide.

14. The method for manufacturing a semiconductor device according to claim 11, wherein the substrate is an amorphous substrate.

15. The method for manufacturing a semiconductor device according to claim 11, wherein the amorphous substrate is an amorphous glass substrate.
